(19) United States
(12) Patent Application Publication
(10) Pub. No.: US 2022/0349057 A1
(43) Pub. Date: Nov. 3, 2022

(54) SEMICONDUCTOR WAFER CARRIER STRUCTURE AND METAL-ORGANIC CHEMICAL VAPOR DEPOSITION EQUIPMENT

(71) Applicant: PlayNitride Display Co., Ltd., Zhunan Township (TW)

(72) Inventors: Yen-Lin LAI, Zhunan Township (TW); Jyun-De WU, Zhunan Township (TW); Chi-Heng CHEN, Zhunan Township (TW)

(73) Assignee: PlayNitride Display Co., Ltd., Zhunan Township (TW)

(21) Appl. No.: 17/466,235

(22) Filed: Sep. 3, 2021

(30) Foreign Application Priority Data
Apr. 28, 2021 (TW) 110115281

(51) Int. Cl. C23C 16/458; H01L 21/687; C23C 16/18

(52) U.S. Cl. CPC C23C 16/4586; H01L 21/68757; C23C 16/4581; C23C 16/18; H01L 21/68785; H01L 33/005

(57) ABSTRACT

A semiconductor wafer carrier structure is provided. The semiconductor wafer carrier structure includes a susceptor and a patterned heat conduction part disposed on the susceptor. At least a portion of the patterned heat conduction part has a different heat conduction coefficient than the susceptor. A metal-organic chemical vapor deposition equipment is also provided. The metal-organic chemical vapor deposition equipment includes a carrier body having a plurality of carrier units. The above semiconductor wafer carrier structure is placed in at least one of the carrier units.

### CROSS REFERENCE TO RELATED APPLICATIONS

This application claims priority of Taiwan Patent Application No. 110115281 filed on Apr. 28, 2021, the entirety of which is incorporated by reference herein.

### BACKGROUND

Technical Field

The present disclosure relates to semiconductor manufacturing equipment, and in particular it relates to a semiconductor wafer carrier structure that includes a patterned heat conduction part.

Description of the Related Art

In metal organic chemical vapor deposition (MOCVD) and other processes where a susceptor can be used to carry wafers, as a method of adjusting the temperature distribution on the susceptor surface, the current mainstream practice is to adjust the surface depth of the susceptor to change the temperature distribution, which in turn affects the characteristics of the grown chip. For example, by adjusting a carrier structure for forming light-emitting diodes (LEDs) to have a uniform temperature distribution, the wavelength uniformity of the light-emitting diode chips can be improved, such that the yield is raised, and the output cost is reduced.

However, although the existing susceptors may satisfy their original intended use, they have not yet fully met demand in various respects. In the existing practice, due to the limitations of mechanical processing for adjusting the surface depth of the susceptor, it is difficult to correct for subtle temperature changes. Therefore, the conventional methods for controlling the temperature of the susceptor will not be able to meet the manufacturing processes of some elements (such as micro LEDs) that require higher dimensional accuracy. How to adjust the temperature distribution of the susceptor surface efficiently and further improve the properties of the wafer it carries (for example, the wavelength distribution of the light-emitting diode chips to be formed subsequently) is still one of the current research topics in the industry.

### BRIEF SUMMARY

In accordance with some embodiments of the present disclosure, a semiconductor wafer carrier structure is provided. The semiconductor wafer carrier structure includes a susceptor; and a patterned heat conduction part disposed on the susceptor, wherein at least a portion of the patterned heat conduction part has a different heat transfer coefficient from the susceptor.

In accordance with some embodiments of the present disclosure, a metal- organic chemical vapor deposition equipment is provided. The metal-organic chemical vapor deposition equipment includes a carrier body having a plurality of carrier units; and the above semiconductor wafer carrier structure placed in at least one of the carrier units.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIG. 1A illustrates a top view of a semiconductor wafer carrier structure, in accordance with some embodiments of the present disclosure.

FIG. 1B illustrates a cross-sectional view of the semiconductor wafer carrier structure, in accordance with some embodiments of the present disclosure.

FIGS. 1C and 1D illustrate cross-sectional views of a semiconductor wafer carrier structure, in accordance with other embodiments of the present disclosure.

FIGS. 2A-2C illustrate top views of a semiconductor wafer carrier structure, in accordance with other embodiments of the present disclosure.

FIG. 3A illustrates a top view of a semiconductor wafer carrier structure, in accordance with other embodiments of the present disclosure.

FIG. 3B illustrates a cross-sectional view of the semiconductor wafer carrier structure, in accordance with other embodiments of the present disclosure.

FIG. 3C illustrates a cross-sectional view of a first outer heat conduction part, in accordance with the embodiments of FIG. 3A and 3B.

FIG. 3D illustrates a cross-sectional view of a second outer heat conduction part, in accordance with the embodiments of FIG. 3A and 3B.

FIG. 3E illustrates a top view of a semiconductor wafer carrier structure, in accordance with other embodiments of the present disclosure.

FIG. 4A illustrates a cross-sectional view of a MOCVD equipment 10, in accordance with some embodiments of the present disclosure.

FIG. 4B illustrates a schematic diagram including a semiconductor wafer carrier structure 100 and a carrier body 400, in accordance with some embodiments of the present disclosure.

### DETAILED DESCRIPTION

The following disclosure provides many different embodiments, or examples, for implementing different features of the subject matter provided. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “about”, “approximately”, and “substantially” used herein generally refer to a given value or a range within 20 percent, preferably within 10 percent, and more preferably within 5 percent, within 3 percent, within 2 percent, within 1 percent, or within 0.5 percent. It should be noted that the amounts provided in the specification are approximate amounts, which means that even “about”, “approximate”, or “substantially” are not specified, the meanings of “about”, “approximate”, or “substantially” are still implied.

Unless otherwise defined, all terms (including technical and scientific terms) used in this article have the same meanings as understood by the person having ordinary skill in the art to which the content of the present disclosure belongs. Terms, such as those defined in commonly used dictionaries, should be interpreted as having meanings consistent with the meanings in related fields, and should not be interpreted in an idealized or overly formal sense, unless explicitly defined here.

Compared to the conventional techniques where the entire surface of the susceptor is covered with a single material, in the semiconductor wafer carrier structure of the present disclosure, a patterned heat conduction part with a different heat conduction coefficient from the susceptor is formed on the susceptor. Therefore, the temperature difference of the susceptor surface may be adjusted more accurately in the process. Alternatively, the temperature difference of the susceptor surface may be adjusted, or various modes of temperature distribution may be generated, according to the temperature adjustment required by the target wafer (such as the temperature adjustment corresponding to the wavelength design of the light-emitting diode chips). For example, in a process using a MOCVD process to form a micro light-emitting diode, a uniform temperature distribution which cannot be achieved by conventional techniques may be generated on the susceptor surface by changing the pattern and the heat conduction coefficient of the patterned heat conduction part, so that the resulting micro light-emitting diode chips may have a uniform wavelength distribution. In other embodiments, the wavelength distribution of the resulting micro light-emitting diode chips may be fine-tuned by adjusting the temperature distribution of the susceptor surface.

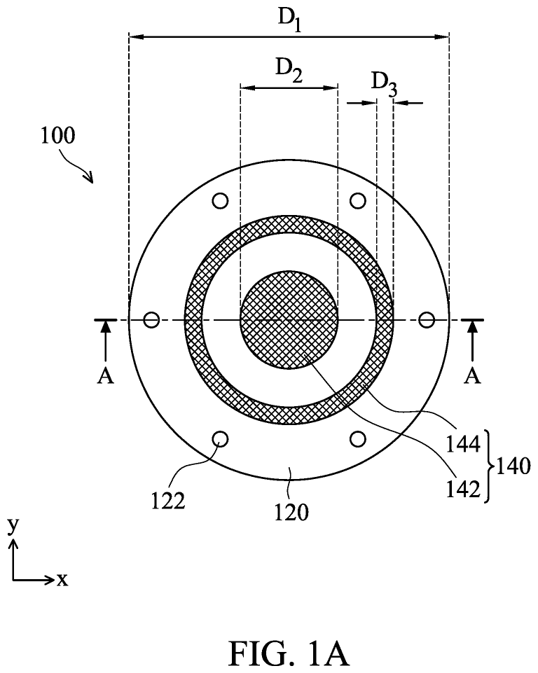

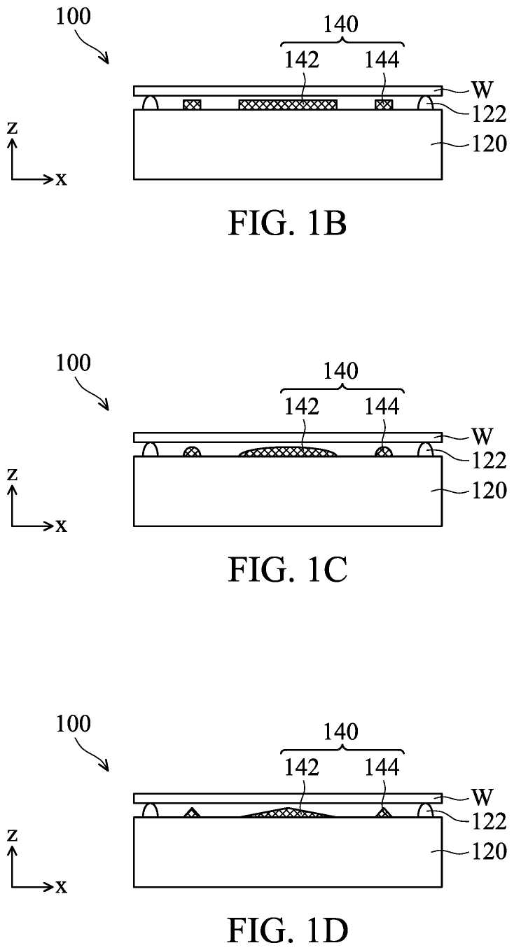

FIG. 1A illustrates a top view of a semiconductor wafer carrier structure 100, in accordance with some embodiments of the present disclosure. In the semiconductor wafer carrier structure 100, a susceptor 120 for carrying a semiconductor wafer is provided, and a patterned heat conduction part 140 is disposed on the surface of the susceptor 120 for carrying the wafer, wherein at least a portion of the patterned heat conduction part 140 has a different heat conduction coefficient from the susceptor 120.

In some embodiments, the material of the susceptor 120 may include graphite, silicon carbide, ceramics, quartz, graphene, another suitable material, or a combination thereof In addition, in some embodiments, the material of the patterned heat conduction part 140 may include silicon carbide (SiC), tantalum carbide (TaC), graphite, ceramics, quartz, graphene, a diamond-like film, another suitable material, or a combination thereof, as long as at least a portion of the patterned heat conduction part 140 has a different heat conduction coefficient than the susceptor 120. For example, for regions on the susceptor 120 where the temperature needs to be raised, a material with a relatively low heat conduction coefficient may be chosen to form a portion of the patterned heat conduction part 140, making it difficult to conduct heat in directions that are parallel to the surface of the susceptor 120, thereby preserving heat. On the other hand, for regions where the temperature needs to be lowered, a material with a relatively high heat conduction coefficient may be chosen to form a portion of the patterned heat conduction part 140, making it is easy to conduct heat in directions that are parallel to the surface of the susceptor 120, thereby dissipating heat. In some embodiments, a portion of the patterned heat conduction part 140 may have the same heat conduction coefficient as the susceptor 120. In this case, the above portion of the patterned heat conduction part 140 may be regarded as a portion of the susceptor 120. By fine-tuning the thickness of the portion of the patterned heat conduction part 140 having the same heat conduction coefficient as the susceptor 120, the heat conduction property of the susceptor 120 may be changed locally to meet the requirements of the process.

The semiconductor wafer carrier structure 100 may carry the wafer for deposition during a MOCVD process, but the application of the present disclosure is not limited to the MOCVD process. The semiconductor wafer carrier structure 100 may also be used in other processes, such as physical vapor deposition (PVD), chemical vapor deposition (CVD), atomic layer deposition (ALD), or the like. In some embodiments since the semiconductor wafer carrier structure 100 may rotate in the above processes to achieve a uniform temperature distribution on the surface of the susceptor 120, the pattern of the patterned heat conduction part 140 may include, for example, a circle, a ring, another symmetrical pattern, or a combination thereof, symmetrically distributing the pattern with respect to the center of the susceptor 120. In addition to achieving uniform temperature distribution, in other embodiments, other modes of temperature distribution may be formed on the surface of the susceptor 120 to meet the manufacturing requirements by changing the pattern and/or the heat conduction coefficient of the patterned heat conduction part.

According to some embodiments of the present disclosure, referring to FIG. 1A, the patterned heat conduction part 140 may include an inner heat conduction part 142 and an outer heat conduction part 144 relatively farther from the center of the susceptor 120 radially. In addition, in the embodiment illustrated is FIG. 1A, the inner heat conduction part 142 is a circular heat conduction part that covers the center of the susceptor 120, and the outer heat conduction part 144 is a ring-shaped heat conduction part. The width of the patterned heat conduction part 140 is not particularly limited in the present disclosure. In some embodiments, the diameter D1 of the susceptor 120 is 25 mm to 250 mm, and the widths of the respective heat conduction parts of the patterned heat conduction part 140 (such as the width D2 of the inner heat conduction part 142 and the width D3 of the outer heat conduction part 144 in FIG. 1A) may be smaller than 34% of the diameter D1 of the susceptor 120, respectively. As illustrated previously, the width or the distribution state of the patterned heat conduction part 140 mainly affects the temperature field distribution of the semiconductor wafer carrier structure 100. Therefore, the mode with smaller widths (or areas) and multi-layered distribution patterns can help to finely control the temperature of each region on the wafer. However, with the evolution of the size of the susceptor 120 or the carried wafer, the difference in the heat conductivity of the materials of each component, or other factors, the preferred ratio of the above widths may be adjusted accordingly.

As illustrated in FIG. 1A, in some embodiments, the susceptor 120 has a plurality of supporting parts 122 for supporting the wafer or a substrate, and the plurality of supporting parts 122 may be symmetrically distributed with respect to the center of the susceptor 120. Although only six supporting parts 122 are illustrated on the susceptor 120 in FIG. 1A, the present disclosure is not limited to this. One of ordinary skill in the art may choose the suitable number, shape, and positions of the supporting parts 122 according to design requirements. In some embodiments, the supporting parts 122 may be formed of the same as the susceptor 120, and the supporting parts 122 may be regarded as a portion of the susceptor 120.

FIG. 1B illustrates a cross-sectional view of the semiconductor wafer carrier structure 100 illustrated from a cross-section A-A of FIG. 1A, in accordance with some embodiments of the present disclosure. The thickness of the patterned heat conduction part 140 is not particularly limited in the present disclosure. For example, in the embodiments where the diameter D1 of the susceptor 120 is 25mm to 250 mm, the thickness of the patterned heat conduction part 140 may be 0.0006% to 0.7% of the diameter D1 of the susceptor 120. As shown in FIG. 1B, the top of the supporting parts 122 may be higher than the top of the patterned heat conduction part 140 in the thickness direction of the susceptor 120 (Z direction), so that the supporting parts 122 may be used to contact the back surface of the wafer W during a MOCVD process, while the patterned heat conduction part 140 does not contact the wafer W directly.

According to some embodiments of the present disclosure, when viewed from the directions parallel to the surface of the susceptor 120, the cross-sectional shapes of the patterned heat conduction part 140 may include a rectangle, a trapezoid, an arc shape, a triangle, combinations thereof, or other suitable shapes. For example, in an embodiment, referring to FIG. 1B, the cross-sectional shapes of the patterned heat conduction part 140 are rectangles. In another embodiment, referring to FIG. 1C, the cross-sectional shapes of the patterned heat conduction part 140 are arc shapes. In yet another embodiment, referring to FIG. 1D, the cross-sectional shapes of the patterned heat conduction part 140 are triangles. Although the inner heat conduction part 142 and the outer heat conduction part 144 are illustrated as the same cross-sectional shape in the embodiments illustrated in FIGS. 1B to 1D (for example, the cross-sectional shapes of the inner heat conduction part 142 and the outer heat conduction part 144 are both rectangles in FIG. 1B), in other embodiments, the inner heat conduction part 142 and the outer heat conduction part 144 may also be formed to have different cross-sectional shapes. By forming the patterned heat conduction part 140 with various cross-sectional shapes, the temperature distribution may be adjusted on the surface of the susceptor 120 according to the manufacturing requirements.

It should be noted that, although the inner heat conduction part 142 and the outer heat conduction part 144 are formed to be separated from each other in the embodiments of FIG. 1A to 1D, multiple heat conduction parts may also be connected to each other in other embodiments of the present disclosure. In addition, in some embodiments, the same material may be used to form the inner heat conduction part 142 and the outer heat conduction part 144, but in other embodiments, the inner heat conduction part 142 and the outer heat conduction part 144 may be formed of materials with different heat conduction coefficients. For example, in some embodiments, the heat conduction coefficient of the outer heat conduction part 144 is larger than the heat conduction coefficient of the inner heat conduction part 142. In various embodiments of the present disclosure, one of ordinary skill in the art may determine the heat conduction coefficient and the relative position of each heat conduction part according to the temperature adjustment of the target wafer.

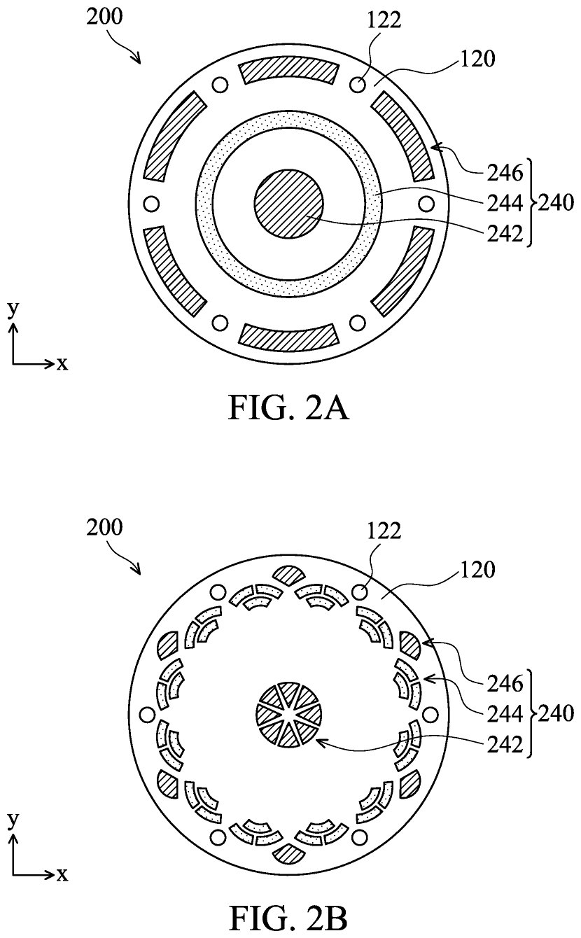

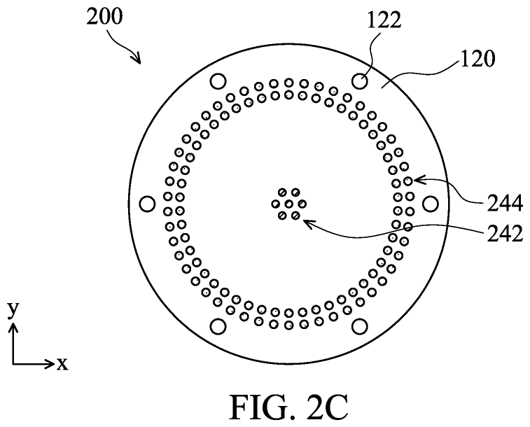

FIG. 2A illustrates a top view of a semiconductor wafer carrier structure 200, in accordance with other embodiments of the present disclosure. To simplify the description, similar elements will be indicated with the same or similar reference numerals as FIG. 1A. Referring to FIG. 2A, a patterned heat conduction part 240 on the susceptor 120 includes an inner heat conduction part 242, and outer heat conduction part 244, and a second outer heat conduction part 246 relatively farther from the center of the susceptor 120, wherein various parts of the first outer heat conduction part 244 and the second outer heat conduction part 246 may be regarded as a plurality of outer heat conduction areas. These outer heat conduction areas are separate from each other and symmetrically distributed with respect to the center of the susceptor 120. In addition, in the embodiment illustrated in FIG. 2A, when viewed from the Z direction, the first outer heat conduction part 244 is a ring-shape, and the second outer heat conduction part 246 has arc-shaped segments spaced apart from each other, wherein the supporting parts 122 of the susceptor 120 are between the above arc shapes. With such configuration, the temperature distribution of the surface of the susceptor 120 may be further adjusted along the outer periphery of the susceptor 120, while using the supporting parts 122 to contact the wafer. Although the second outer heat conduction part 246 is illustrated as six outer heat conduction areas spaced apart from each other in FIG. 2A, in other embodiments, the shape and position of each outer heat conduction area may also be determined according to the required temperature adjustment of the target wafer, and the number of the heat conduction areas included in each heat conduction part may be further determined. In some embodiments, the inner heat conduction part 242, the first outer heat conduction part 244, and the second outer heat conduction part 246 may be formed of the same material. In other embodiments, various portions of the inner heat conduction part 242, the first outer heat conduction part 244, and the second outer heat conduction part 246 may be formed of completely different materials.

FIGS. 2B and 2C illustrate top views of the semiconductor wafer carrier structure 200, in accordance with other embodiments of the present disclosure. For simplicity of description, similar elements will be indicated with the same or similar reference numerals as FIGS. 1A and 2A. One of ordinary skill in the art may use heat conduction parts with various shapes according to the temperature adjustment required by the target wafer, and even use a combination of multiple heat conduction areas to form respective heat conduction part and the required profile.

In some embodiments, each heat conduction part may include a plurality of heat conduction areas with various shapes, respectively. As shown is FIG. 2B, the patterned heat conduction part 240 on the susceptor 120 may include the inner heat conduction part 242, the first outer heat conduction part 244, and the second outer heat conduction part 246 relatively farther from the center of the susceptor 120 radially. In the embodiment shown in FIG. 2B, the inner heat conduction part 242 includes a plurality of sectored inner heat conduction areas spaced apart from each other and symmetrical with respect to the center of the susceptor 120, and the arcs of these sectored inner heat conduction areas collectively form a circular profile. Various portions of the first outer heat conduction part 244 and the second outer heat conduction part 246 of the embodiment shown in FIG. 2B may be regarded as a plurality of outer heat conduction parts, and these outer heat conduction parts are separate from each other and symmetrically distributed with respect to the center of the susceptor 120. In the embodiment shown in FIG. 2B, the first outer heat conduction part 244 includes a plurality of arc-shaped outer heat conduction areas, and the distribution of these arc-shaped outer heat conduction areas collectively generally form a ring-shaped profile. In addition, the second outer heat conduction part 246 is sectors spaced apart from each other, wherein the supporting parts 122 of the susceptor 120 are between the spaces of these sectors. With such configuration, the temperature distribution of the surface of the susceptor 120 may be further adjusted along the outside of the susceptor 120, while the supporting parts 122 are used to contact the wafer. Although the second outer heat conduction part 246 is illustrated as six outer heat conduction areas spaced apart from each other in FIG. 2B, in other embodiments, the shape and position of each outer heat conduction area may also be determined according to the temperature adjustment required by the target wafer, and the number of the heat conduction areas included in each heat conduction part may be further determined. In some embodiments, the inner heat conduction part 242, the first outer heat conduction part 244, and the second outer heat conduction part 246 may be formed of the same material. In other embodiments, the inner heat conduction part 242, the first outer heat conduction part 244, and the second outer heat conduction part 246 may be formed of materials which are not completely the same.

In some embodiments, as shown is FIG. 2C, the patterned heat conduction part 240 on the susceptor 120 includes the inner heat conduction part 242, and the first outer heat conduction part 244 relatively farther from the center of the susceptor 120 radially, and the patterned heat conduction part 240 is completely formed of a plurality of circular heat conduction areas. In the embodiment illustrated in FIG. 2C, the inner heat conduction part 242 includes a plurality of circular inner heat conduction areas spaced apart from each other and symmetrical with respect to the center of the susceptor 120, and these circular inner heat conduction areas collectively form a substantially circular profile on their periphery. In the embodiment shown in FIG. 2C, the first outer heat conduction part 244 includes a plurality of circular outer heat conduction areas spaced apart from each other and relatively farther from the center of the susceptor 120, wherein these circular outer heat conduction areas are symmetrical with respect to the center of susceptor 120, and the distribution of these circular outer heat conduction areas collectively form a ring profile. Although the inner heat conduction part 242 is illustrated as formed of seven circular inner heat conduction areas in FIG. 2C, and the first outer heat conduction part 244 is illustrated as a pattern of a ring-shaped arrangement having two circular outer heat conduction areas spaced apart from each other radially, the present disclosure is not limited to this. The shape and position of each heat conduction area may be determined according to the temperature adjustment required by the target wafer, and the number of heat conduction areas included in each heat conduction part may be further determined. In some embodiments, the various conduction areas of the inner heat conduction part 242 and the first outer heat conduction part 244 may be formed of the same material. In other embodiments, the various conduction areas of the inner heat conduction part 242 and the first outer heat conduction part 244 may be formed of materials which are not completely the same.

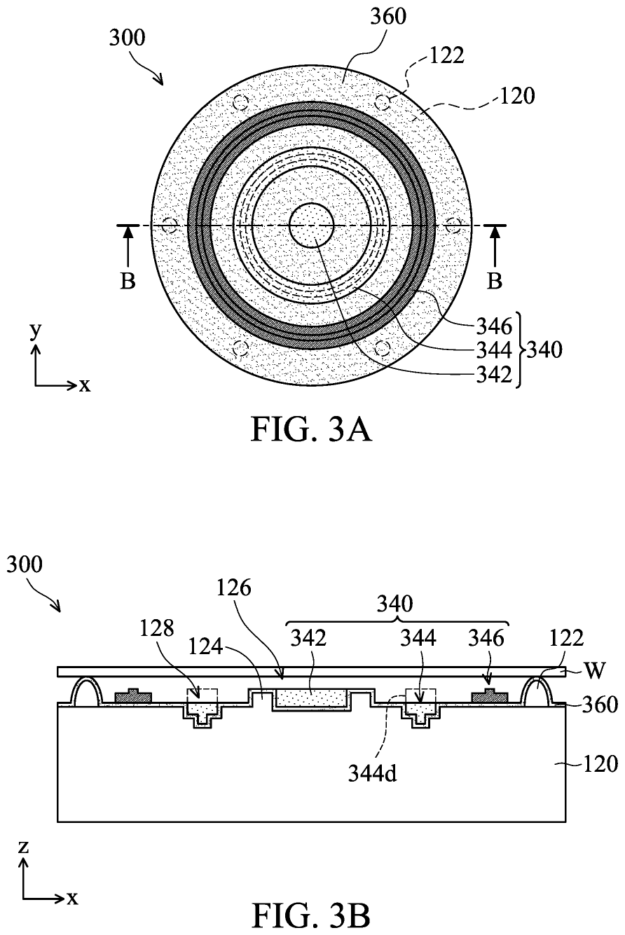

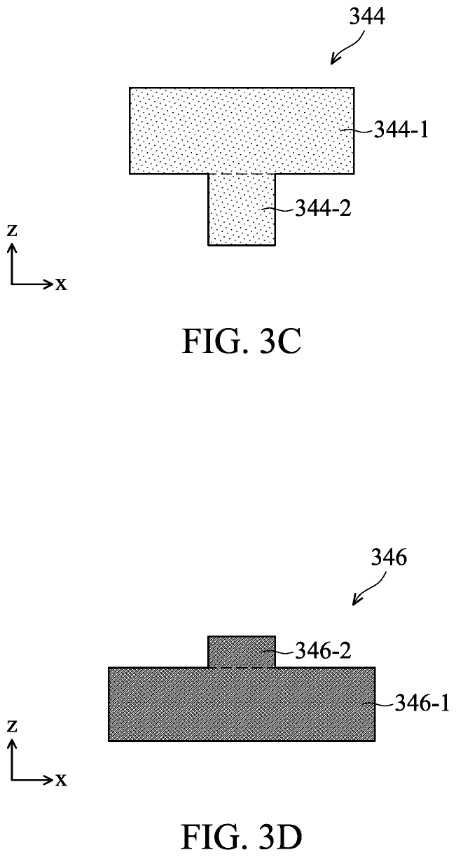

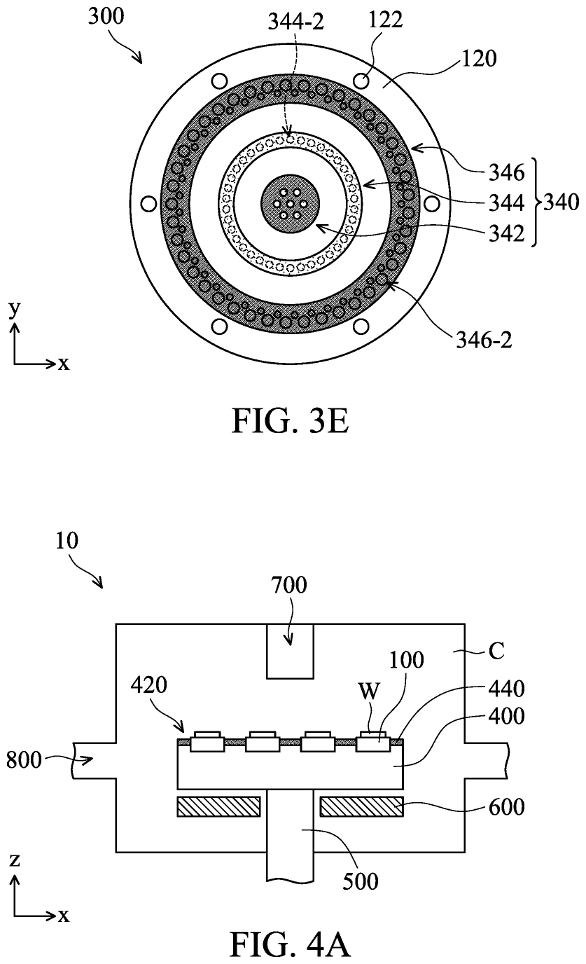

FIGS. 3A and 3B illustrate a top view and a cross-sectional view of a semiconductor wafer carrier structure 300 respectively, in accordance with other embodiments of the present disclosure, wherein FIG. 3B is the cross-sectional view corresponding to a cross-section B-B in FIG. 3A. For simplicity of description, similar elements will be indicated with the same or similar reference numerals as FIG. 1A. Referring to FIGS. 3A and 3B, a patterned heat conduction part 340 includes an inner heat conduction part 342, a first outer heat conduction part 344, and a second outer heat conduction part 346 relatively farther from the center of the susceptor 120 radially. In some embodiments, various trenches and/or protrusions may be formed on the surface of the susceptor 120. In some embodiments, as shown in FIG. 3B, the surface of the susceptor 120 includes a protrusion 124, a trench 126 surrounded by the protrusion 124, and a trench 128 located outside the protrusion 124 radially. In some embodiments, portions of the patterned heat conduction part 340 (the inner heat conduction part 342 and the first outer heat conduction part 344) are embedded in the trenches 126 and 128 respectively, while a portion of the heat conduction part 340 (the second outer heat conduction part 346) is disposed as protruding from the surface of susceptor 120, and its sidewalls are not surrounded by the susceptor 120. In some embodiments, mechanical processing, photolithography process, etching process, combinations thereof, or other suitable processes may be utilized to form the structure on the surface of the susceptor 120, such as the protruding 124, the trench 126, and the trench 128.

In some embodiments, referring to FIG. 3A and 3B, the semiconductor wafer carrier structure 300 may further comprise a protective layer 360 covering the surface of the susceptor 120, and the patterned heat conduction part 340 is disposed on the protective layer 360. In addition, in some embodiments, the protective layer 360 may also cover the surfaces of the supporting parts 122, so that the semiconductor wafer carrier structure 300 is in contact with the back surface of the wafer with the protective layer 360. Since the process gases used in the MOCVD process may be corrosive to the materials of the susceptor 120 and/or the supporting parts 122, by covering the surfaces of the susceptor 120 and/or the supporting parts 122 with the protective layer 360, the corrosion of the susceptor 120 and/or the supporting parts 122 by the process gases (such as NH₃ or the like) may be prevented.

In some embodiments, the material of the protective layer 360 may include silicon carbide, tantalum carbide (TaC), graphite, ceramics, graphene, diamond-like film, another suitable material, or a combination thereof, and the material of the protective layer 360 is preferably a material with a heat conduction coefficient close to that of the susceptor 120. In some embodiments of the present disclosure, the materials of at least a portion of the patterned heat conduction part 340 and the protective layer 360 are different, and the thickness of these portions of the patterned heat conduction part 340 is not limited in the present disclosure. In some embodiments, the heat conduction coefficients of the patterned heat conduction part 340 and the protective layer 360 are different. In addition, although the protective layer 360 is formed to cover the surface of the susceptor 120 conformally in the embodiment of FIG. 3B, in other embodiments, the protective layer 360 may also be formed to have a structure with a thickness variation or a height variation by processes such as photolithography, etching, or the like.

Although the top surfaces inner heat conduction part 342 and the first outer heat conduction part 344 are formed to be level with the top surface of the surrounding protective layer 360 in the embodiment of FIG. 3B, in other embodiments, the top surfaces of the inner heat conduction part 342 and the first outer heat conduction part 344 (which are embedded in trenches 126 and 128 respectively) may also be formed to be higher than the top surface of the susceptor 120 or the protective layer 360 surrounding the trenches 126 and 128, so that the inner heat conduction part 342 and/or the first outer heat conduction part 344 is closer to the wafer (for example, by substantially leveling the top surface of the first outer heat conduction part 344 and the top surface of the inner heat conduction part 342 or the second outer heat conduction part 346), and thereby the local heat mass of the semiconductor wafer carrier structure 300 may be increased, which changes the temperature distribution of the surface of the susceptor 120. For example, in some embodiments, the first outer heat conduction part 344 may be formed to have a higher top surface than the surrounding susceptor 120 or the protective layer 360. This way, the position of the top surface of the first outer heat conduction part 344 may vary within the range outlined by the dashed box 344d illustrated in FIG. 3B. The upper edge of the dashed box 344d is higher than the top surface of the surrounding susceptor 120 or the protective layer 360, but it is not in contact with the lower surface of the wafer W.

FIGS. 3C and 3D illustrate cross-sectional views of the first outer heat conduction part 344 and the second outer heat conduction part 346 respectively, in accordance with the embodiment of FIGS. 3A and 3B. Referring to FIG. 3C, the first outer heat conduction part 344 includes a first portion 344-1 and a second portion 344-2 lower in the z direction; and referring to FIG. 3D, the second outer heat conduction part 346 includes a first portion 346-1 and a second portion 346-2 lower in the z direction. As shown in FIGS. 3C and 3D, on the xz plane, the cross-sectional shapes of the first outer heat conduction part 344 and the second outer heat conduction part 346 may be regarded as a combination of two rectangles with different heights in the z direction, respectively. In other embodiments, the cross-sectional shape of the patterned heat conduction part 340 may also be formed as a combination of a rectangle, a trapezoid, an arc shape, a triangle, or other suitable shapes.

Although the second portion 344-2 of the first outer heat conduction part 344 and the second portion 346-2 of the second outer heat conduction part 346 are formed as ring-shapes symmetrically distributed with respect to the center of the susceptor 120 in the embodiments of FIG. 3A, in some other embodiments, the cross-sections of the second portions 344-2 and 346-2 parallel to the surface of the susceptor 120 (the cross-sections perpendicular to the z direction) may also be formed to have a plurality of circles. FIG. 3E illustrates a top view of the semiconductor wafer carrier structure 300, in accordance with such embodiment. Referring to FIG. 3E, the patterned heat conduction part 340 includes the inner heat conduction part 342, the first outer heat conduction part 344, and the second heat conduction part 346 relatively farther from the center of the susceptor 120 radially, wherein the second portion 344-2 of the first outer heat conduction part 344 and the second portion 346-2 of the second outer heat conduction part 346 are formed to have a plurality of circles with different sizes on the cross-sections parallel to the surface of the susceptor 120. By forming the patterned heat conduction part 340 with different structures, the temperature distribution may be adjusted on the surface of the susceptor 120 according to the manufacturing requirements. In addition, in the embodiment shown in FIG. 3E, the inner heat conduction part 342 has a plurality of heat conduction areas of circular trenches, and the heat conduction areas of circular trenches may also have a depth variation. For example, the inner heat conduction part 342 of FIG. 3E may be formed of a larger outer circle with a shallower depth and a plurality of smaller circular trenches with a deeper depth, Certainly, the shape, pattern distribution, or relative height of these inner heat conduction part 342 (and the entire patterned heat conduction part 340) may have various variants, depending on the temperature field distribution of the wafer, thereby changing the heat mass of the surface of the susceptor 120 to generate corresponding temperature distributions.

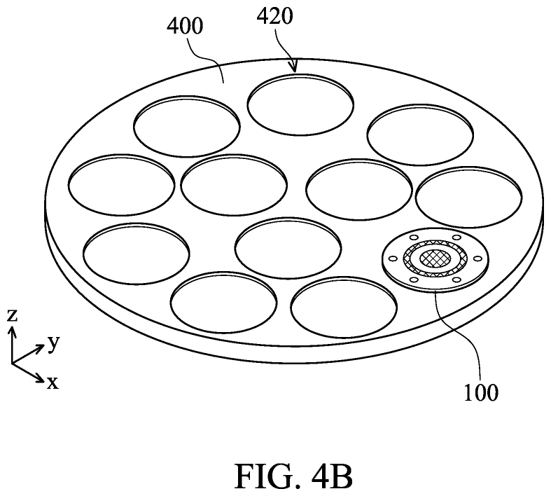

FIG. 4A illustrates a cross-sectional view of a MOCVD equipment 10, in accordance with some embodiments of the present disclosure. FIG. 4B illustrates a schematic diagram including a carrier body 400 and the semiconductor wafer carrier structure 100s, in accordance with some embodiments of the present disclosure. Referring to FIG. 4A, the carrier body 400 for placing the semiconductor wafer carrier structure (the semiconductor wafer carrier structures 100 is used as an exemplary semiconductor wafer carrier structure in FIG. 4 and following descriptions) is included in a chamber C of the MOCVD equipment 10. In some embodiments, the carrier body 400 has a plurality of carrier units 420, and one or more semiconductor wafer carrier structure 100 carrying the wafer is placed in the plurality of carrier units 420. In addition, in some embodiments, as shown in FIG. 4B, the plurality of carrier units 420 may be symmetrically distributed with respect to the center of the carrier body 400.

The carrier units 420 may be trenches or other structures for placing the semiconductor wafer carrier structure 100s. For example, in the embodiment of FIG. 4A, the upper surface of the carrier body 400 has a spacer 440. By forming the spacer 440 as a particular structure, the carrier units 420 for placing the semiconductor wafer carrier structure 100s may be formed on the upper surface of the carrier body 400. However, in some other embodiments, the upper surface of the carrier body 400 may also be formed as other structures for placing the semiconductor wafer carrier structure 100s.

Although the embodiment of having the plurality of carrier units 420 and placing the plurality of semiconductor wafer carrier structures on the carrier body 400 is described above, in other embodiments, there may be only one carrier unit 420 and only one semiconductor wafer carrier structure placed on the carrier body 400.

Referring to FIG. 4A, in some embodiments of the present disclosure, the MOCVD equipment 10 further includes a support member 500 below the carrier body 400, wherein the support member 500 may be used to rotate the entire carrier body 400 along the z axis. As a result, in these embodiments, by placing one or more semiconductor wafer carrier structure 100 carrying the wafer to at least one of the carrier units 420 and rotating the entire carrier body 400 on its center (while each semiconductor wafer carrier structure 100 will rotate on the center of the carrier body 400), a particular temperature distribution may be generated on the surface of the susceptor of each semiconductor wafer carrier structure 100 during the MOCVD process. In addition, in some embodiments, apart from rotating the entire carrier body 400 on its center, the one or more wafer carrier structure 100 may also rotate on its respective center, and thereby further adjusting the temperature of the surface of the susceptor. As shown in FIG. 4A, in some embodiments, the MOCVD equipment 10 may also include a heater 600 below the carrier body 400 and/or surrounding the support member 500. The heater 600 may be a feature for generating various patterns of temperature distributions and may have a heat conduction structure with a patterned design that can affect the temperature distribution, or the like, which is not limited in the present disclosure. Furthermore, in some embodiments, the MOCVD equipment 10 further includes a nozzle 700 for injecting process gases into the chamber C and venting ports 800 for discharging the process gases. Although the nozzle 700 is illustrated as a single nozzle 700 directly above the chamber C in FIG. 4A, in some other embodiments, a plurality of smaller nozzles 700 may also be formed above the chamber C, which is not limited in the present disclosure.

As described above, the present disclosure provides a semiconductor wafer carrier structure and a MOCVD equipment including such structure. Compared to the conventional techniques where the entire surface of the susceptor is covered with a single material, in the semiconductor wafer carrier structure of the present disclosure, a patterned heat conduction part with a different heat conduction coefficient from the susceptor is formed on the susceptor. Therefore, the temperature difference of the susceptor surface may be adjusted more accurately in the process. Alternatively, the temperature difference of the susceptor surface may be adjusted, or various modes of temperature distribution may be generated, according to the temperature adjustment required by the target wafer (such as the temperature adjustment corresponding to the wavelength design of the light-emitting diode chips). For example, in a process using a MOCVD process to form a micro light-emitting diode, a uniform temperature distribution which cannot be achieved using conventional techniques may be generated on the susceptor surface by changing the pattern and the heat conduction coefficient of the patterned heat conduction part, so that the resulting micro light-emitting diode chips may have uniform wavelength distributions. In other embodiments, the wavelength distribution of the resulting micro light-emitting diode chips may be fine-tuned by adjusting the temperature distribution of the susceptor surface.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor wafer carrier structure, comprising:
a susceptor; and
a patterned heat conduction part disposed on the susceptor,
wherein at least a portion of the patterned heat conduction part has a different heat conduction coefficient than the susceptor.

2. The semiconductor wafer carrier structure as claimed in claim 1, wherein the patterned heat conduction part is symmetrically distributed with respect to a center of the susceptor.

3. The semiconductor wafer carrier structure as claimed in claim 1, wherein the patterned heat conduction part comprises an inner heat conduction part and an outer heat conduction part relatively farther from a center of the susceptor radially.

4. The semiconductor wafer carrier structure as claimed in claim 3, wherein the inner heat conduction part and the outer heat conduction part are separate from each other.

5. The semiconductor wafer carrier structure as claimed in claim 3, wherein heat conduction coefficients of the inner heat conduction part and the outer heat conduction part are different.

6. The semiconductor wafer carrier structure as claimed in claim 3, wherein the heat conduction coefficient of the outer heat conduction part is larger than the heat conduction coefficient of the inner heat conduction part.

7. The semiconductor wafer carrier structure as claimed in claim 3, wherein the inner heat conduction part covers the center of the susceptor.

8. The semiconductor wafer carrier structure as claimed in claim 3, wherein the outer heat conduction part is ring-shaped.

9. The semiconductor wafer carrier structure as claimed in claim 3, wherein the outer heat conduction part comprises a plurality of outer heat conduction areas, and the plurality of outer heat conduction areas are separate from each other and symmetrically distributed with respect to the center of the susceptor.

10. The semiconductor wafer carrier structure as claimed in claim 1, wherein the cross-sectional shape of the patterned heat conduction part comprises a rectangle, a trapezoid, an arc shape, a triangle, or a combination thereof.

11. The semiconductor wafer carrier structure as claimed in claim 1, wherein the surface of the susceptor comprises a trench and/or a protrusion.

12. The semiconductor wafer carrier structure as claimed in claim 11, wherein a portion of the patterned heat conduction part is embedded in the trench.

13. The semiconductor wafer carrier structure as claimed in claim 1, further comprising:
a protective layer covering the surface of the susceptor, wherein the patterned heat conduction part is disposed on the protective layer.

14. The semiconductor wafer carrier structure as claimed in claim 13, wherein a material of the patterned heat conduction part and the protective layer comprises silicon carbide (SiC), tantalum carbide (TaC), graphite, ceramics, quartz, graphene, diamond-like film, or a combination thereof.

15. The semiconductor wafer carrier structure as claimed in claim 14, wherein at least a portion of the patterned heat conduction part is formed of a different material than the protective layer.

16. The semiconductor wafer carrier structure as claimed in claim 14, wherein heat conduction coefficients of the patterned heat conduction part and the protective layer are different.

17. The semiconductor wafer carrier structure as claimed in claim 1, wherein a material of the susceptor comprises graphite, silicon carbide, or a combination thereof.

18. The semiconductor wafer carrier structure as claimed in claim 1, wherein the susceptor has a plurality of supporting parts, and the plurality of supporting parts are located on the edge of the susceptor.

19. The semiconductor wafer carrier structure as claimed in claim 18, wherein the top of the plurality of supporting parts are higher than the top of the patterned heat conduction part in the thickness direction of the susceptor.

20. A metal-organic chemical vapor deposition (MOCVD) equipment, comprising:
a carrier body having a plurality of carrier units; and
the semiconductor wafer carrier structure of claim 1 placed in at least one of the carrier units.
